(19) United States
(12) Patent Application Publication
(10) Pub. No.: US 2026/0105206 A1
(43) Pub. Date: Apr. 16, 2026

(54) Circular/Sustainable Goods and Services Exchange (SGSE) For The Kitchen Renovation Industry

(71) Applicant: James J. Gurulé, Danville, CA (US)

(72) Inventor: James J. Gurulé, Danville, CA (US)

(21) Appl. No.: 19/355,587

(22) Filed: Oct. 10, 2025

Related U.S. Application Data
(60) Provisional application No. 63/707,417, filed on Oct. 15, 2024.

(51) Int. Cl. G06F 30/13; G06Q 30/02; G06Q 50/08

(52) U.S. Cl. CPC G06F 30/13; G06Q 30/0278; G06Q 50/08

(57) ABSTRACT

Techniques are disclosed for a circular or sustainable goods and services exchange/marketplace/platform for reducing the environmental footprint of kitchen renovation projects. The platform is used to capture an existing kitchen scene input and leverages AI and computer vision techniques for producing a 3D digital twin file of the kitchen. Subsequently digital assets corresponding to the physical assets of the kitchen are uploaded onto the platform by the homeowner. The platform warehouses these digital assets to facilitate their reuse for a “second life” in a new kitchen or an existing kitchen. With the ability to scale rapidly, the platform creates a network effect that benefits all participants. As more users join the platform, the pool of available resources grows, attracting even more users. This creates a positive-feedback loop for reducing the environmental footprint of the kitchen renovation industry.

### RELATED APPLICATIONS

This application claims priority from U.S. Provisional Patent Application No. 63/707,417 filed on Oct. 15, 2024, and which is incorporated by reference herein for all purposes in its entirety.

### FIELD OF THE INVENTION

This invention is generally related to the field of circular economy. More specifically, this invention is related to the systems and methods for performing kitchen renovation projects in an eco-friendly or sustainable or circular manner. Consequently, the invention facilitates a variety of ESG (Environmental, Social and Governance) initiatives.

### BACKGROUND ART

According to a 2017 report by the National Kitchen Bath Association (NKBA), over 10 million kitchen renovation projects are performed per year in the United States alone. Approximately 1 out of 10 private homes have performed a kitchen renovation.

The total kitchen renewal or remodeling market value was $49.7 billion in 2023 and is rising.

Consequently, construction and demolition debris has become an increasingly pressing economic, social, and environmental concern across the world. In recent years, with the increase in the awareness around sustainability, ESG and resource management, the implementation of circular economy (CE) has emerged as a potential model for minimizing the negative impact of construction and demolition (C&D) wastes.

Globally, construction, renovation, and demolition activities are responsible for approximately 25% of all solid waste, and the construction sector accounts for nearly 50% of the natural resources extracted worldwide. The generated waste has a high potential for recovery. However, according to the Global Waste Management Outlook that was issued by the International Solid Waste Association (ISWA) and the United Nations Environmental Program (UNEP), about 85% of the total generated solid waste worldwide is disposed of in landfills. This is due to very low reuse and recycling rates, and thus contributing to our existing sustainability crisis.

In the United States, the U.S. Environmental Protection Agency (EPA) estimated that 600 million tons of C&D debris were generated in the United States in 2018, which is more than twice the amount of generated household waste (disposable materials generated by households such as food and paper). C&D waste generation in the U.S. increased by 342% from 1990 to 2018.

Construction related debris is a growing problem, with no slowdown in sight. The kitchen renovation industry in the U.S. contributes its fair share to the debris as over 10 million households (roughly one in ten of all households) will undertake a kitchen renovation project each year, with the vast majority of project debris ending up in landfill. Focus on the environmental impact of such renovation projects continues to increase as homeowners and communities become more environmentally conscious and governmental agencies institute new goals and regulations around diversion of construction and demolition debris.

Therefore, the shift towards sustainable kitchens is much more than a trend. It is a shift from a linear economy to a circular economy, and is a part of a larger movement towards responsible living and conscious design. As one sign of a generational shift, 70% of the Millennials and 75% of the Gen Z population is focused on sustainability options.

In as far as striving to improve efficiencies of kitchen remodeling projects, the teachings of several prior art attempts are available to a practitioner. U.S. Patent Publication No. 2024/0087004 A1 to Besecker et al. discloses systems and methods for composing a virtual environment. The virtual environment may represent a room or other space having specified parameters. The system may facilitate placement of three-dimensional (3D) models of objects in the virtual environment, where the 3D models correspond to one or more objects depicted in a two-dimensional (2D) image. The placement of the 3D models is algorithmically determined based on placement rules to generate an arrangement of the 3D models based on a layout of the one or more objects in the 2D image. The system can execute the placement rules to algorithmically determine placement locations of the 3D models corresponding to objects depicted in the 2D image.

U.S. Patent Publication No. 2023/0394765 A1 to Tang et al. teaches various implementations that include devices, systems, and methods for providing a 3D room plan that combines 2D shapes representing elements of a room that are approximately planar (e.g., walls, wall openings, windows, doors, etc.) with 3D primitives representing non-planar elements (e.g., tables, chairs, appliances, etc.). According to their teachings, a 3D room plan is a 3D representation of a room or other physical environment that generally identifies or otherwise represents 3D positions of one or more walls, floors, ceilings, other boundaries, other regions, windows, doors, openings, and 3D objects (e.g., objects having significant height, width, and depth in 3 dimensions) within the environment. For example, a 3D floorplan using 2D shapes to represent walls, windows, doors, etc. may be combined with 3D primitives such as 3D bounding boxes representing 3D objects to form a 3D room plan.

U.S. Patent Publication No. 2023/0099352 A1 to Cantwell et al. describes a method implemented with instructions executed by a processor that include receiving a digital image of an interior space. At least one detected object is identified within the digital image. Dimensions of the detected object are determined. Image segmentation is applied to the digital image to produce a segmented image. Edges are detected in the segmented image to produce a combined output image. Geometric transformation, field of view and depth correction are applied to the combined output image to correct for image distortion to produce a geometrically transformed digital image. Dimensions are applied to the geometrically transformed digital image at least partially based on the dimensions of the detected object to produce a dimensionalized floorplan.

U.S. Patent Publication No. 2021/0019453 A1 to Yang et al. discloses systems and methods for generating a furnishing plan for a property. An exemplary system includes a communication interface configured to receive a floorplan of the property and a neural network model. The system further includes at least one processor configured to obtain structural data of the property based on the floorplan and learn furnishing information by applying the neural network model to the floorplan and the structural data. The furnishing information identifies one or more furnishing objects, positions of the respective furnishing objects placed in the floorplan, and dimensions of the respective furnishing objects. The at least one processor is also configured to generate the furnishing plan for the property based on the furnishing information.

U.S. Patent Publication No. 2024/0193886 A1 to Sadalgi et al. teaches method and systems for generating, storing, and using a digital representation of a property. The digital representation of the property may include a property profile comprising information associated with an address of the property. It may also include the property profile comprising multiple digital representations of multiple respective indoor and/or outdoor spaces of the property. It may also include a user profile comprising metadata associated with an owner and/or an occupant of the property. The digital representation of the property may be used in various applications including shopping (e.g., shopping for products, like furniture, which may be purchased for use in the property), provisioning of services for the property (e.g., design services, contractor services, etc.), and various other applications.

It is understood that traditional kitchen renovations follow a wasteful linear model, that is, natural resources are used to make products that are bought, used and disposed of. FIG. 1 presents the difficulties and the missed opportunities in the existing donation process of a linear economic model 10. In contrast to the various linear economy solutions provided above, in the circular model, instead of being disposed of, products and materials are kept in circulation through processes such as reuse and refurbishment. There are no teachings in the prior art that address the need of circularity of economy specifically to kitchen renovation projects.

While there have been some efforts to encourage and divert kitchen renovation debris at the local level, they fall short of comprehensively addressing the issues. For example, charitable organization Habitat for Humanity® accepts used materials, such as appliances, doors, windows and cabinets in good condition from a home, and resells them in its “ReStores”. Similarly, architectural salvage or used material retail outlets buy materials and place them on a secondary marketplace for such materials. While these are good examples of such efforts, in both the cases, the process is cumbersome and difficult and is not scalable. As a result, the status quo discourages any real progress towards solving the sustainability crisis that the world is facing. The present technology fulfills these shortfalls as taught in this disclosure.

Today, inefficiencies are present at every level in the lifecycle of planning of a kitchen renovation project. The root of these inefficiencies includes confusing and outdated measuring systems, lack of recognized industry standards and uniform nomenclature. The root causes of the inefficiencies further include manual processes prone to error, poor communication and poor collaboration among the participants in the process. The majority of existing systems for measurement are manual and those systems that are automated are not integrated into the other parts of the process.

The various stakeholders work largely in isolation from one another without the means to easily and clearly communicate and without a central repository to keep all written communication and documentation associated with the project. Lack of a seamless end-to-end systems results in a dysfunctional and fragmented process, often laden with unnecessary delays, errors and expense, and leading to a poor experience for all participants in the process. The present technology addresses the above shortcomings as provided in this disclosure.

Further, disrupting conventional linear material flows and transitioning the building sector to embrace circular economy principles is critical to overcoming the difficulties of the prior art in a meaningful way. This effort requires that one rethinks the way resources are used and managed in the built environment. A practical solution as provided by the instant technology emphasizes the importance of retaining the value of existing materials and reintegrating them back into the system.

In order to meet the challenges faced by the industry, a scalable and automated solution is needed to break down the barriers to adoption, and to overcome technological gaps, market-related challenges, regulatory barriers, financial constraints, lack of collaboration and education, logistics, etc. Specifically for the kitchen renovation business, the principles of reusing and refurbishing existing materials, as opposed to recycling, are key to reducing the environmental impact and carbon footprint that the 10 million kitchen renovation projects will have each year. The present technology provides such a solution that addresses the aforementioned needs of the industry as taught throughout this disclosure.

### OBJECTS OF THE INVENTION

In view of the shortcomings of the prior art, it is an object of the invention to provide a circular or sustainable goods and services exchange (SGSE) or platform that is based on the principles of a circular economy.

It is also an object of the invention to allow homeowners to upload the image files of their respective kitchens on to the SGSE.

It is also an object of the invention to generate via SGSE, three-dimensional (3D) digital twin files containing the digital assets of the kitchens of the homeowners.

It is further an object of the invention to allow the homeowners to post the digital assets of their respective kitchen onto the instant SGSE.

It is further an object of the invention to allow a homeowner to reuse used kitchen assets posted by another homeowner onto the platform.

It is also an object of the invention to generate CAD or layout files that can be used by contractors/stakeholders in order to estimate budget with labor and material costs and to perform kitchen deconstruction and renovation projects for the respective homeowners.

It is further an object of the invention to generate diversion reports for kitchen projects that may be provided by the respective homeowners to appropriate government agencies.

Still other objects and advantages of the invention will become apparent upon reading the summary and the detailed description in conjunction with the drawing figures.

### SUMMARY OF THE INVENTION

The objects and advantages of the invention are achieved by the apparatus and methods of a circular or sustainable goods and services exchange (SGSE) or platform that performs a variety of circular economy functions for and by a variety of users. One set of users supported by the system are the homeowners. By way of example, a first homeowner and a second homeowner scan their existing kitchens using appropriate imaging systems such as their respective digital cameras. Then they upload the resultant image files i.e. a first image file and a second image file of their respective first and second kitchens onto the instant SGSE platform. An image file may be a video file or a file containing a series of still images or it may just be a still image file.

Then by utilizing artificial intelligence (AI) and/or computer vision techniques based on the instant principles, the SGSE processes the image files and produces corresponding three dimensional (3D) digital twin files for the respective kitchens. Each of the 3D digital twin files contains the digital assets recognized by the instant AI and/or computer vision technologies corresponding to the physical assets in the respective kitchens. More specifically, the first 3D digital twin file contains the digital assets corresponding to the physical assets in the first kitchen. Similarly, the second 3D digital twin file contains the digital assets corresponding to the physical assets in the second kitchen.

Instant SGSE allows the first and second homeowners to post the first and second digital assets respectively onto the instant platform. The inventory of such existing kitchen assets then becomes available for reuse by all homeowners onboarded onto the system based on the principles of a circular economy. Let us assume that the first homeowner is simply interested in posting their digital assets inventory for purchase and reuse by others.

Let us further assume that the second homeowner is interesting in acquiring the inventory posted by other homeowners, including the first homeowner.

For this purpose, the instant SGSE/platform would allow the first homeowner to post or warehouse their digital assets inventory for free. This is done in order to encourage homeowners to post inventory from their kitchen renovation projects that would otherwise go to waste. On the other hand, the instant platform charges a subscription or fee from the second homeowner for acquiring the posted inventory. The first homeowner may be performing a kitchen renovation project of their existing kitchen. The second homeowner may also be renovating their existing kitchen. Alternatively, the second homeowner may be constructing their new kitchen anew and in which case they would not be posting any digital assets inventory from their existing kitchen.

Regardless, instant SGSE then generates a computer-aided design (CAD) or a floorplan or a layout or a blueprint file for the first kitchen. The first CAD file would be consumable by a first contractor or tradesman for the deconstruction or demolition of their existing or first kitchen. The SGSE also generates a second CAD/floorplan/layout/blueprint file for the second kitchen. The second CAD file is consumed by a second contractor/tradesman for the renovation i.e. deconstruction and construction of the second kitchen of the second homeowner.

Furthermore, instant SGSE also produces a first diversion report for the first homeowner for their kitchen deconstruction and/or renovation project and a second diversion report for the second homeowner for their kitchen renovation project. These diversion reports can be provided by the respective homeowners to respective government agencies/authorities for building permits.

Another set of users supported by instant SGSE are deconstruction company users or appraisers or assessors. These users can access the system and estimate/appraise or assess the value of digital assets posted by respective homeowner on the instant platform per above discussion. Yet another set of users supported by the platform are charitable organization users. Such users, who may also be or the same as assessors, can access the digital assets posted on the platform for donation to a charitable cause. In return, the corresponding homeowner may receive a tax benefit and/or monetary compensation. Yet another type of users are IT administrations or admins who are responsible for maintaining a stable and smooth operation of the system.

In the preferred embodiment, the instant SGSE comprises of a variety of computer systems or layers or modules. These include a user experience (UX) module, an application service module, an artificial intelligence (AI), computer vision and analytics module, a data infrastructure module, an external integrations module and an administration and monitoring module. In the same or a related embodiment, the AI, computer vision and analytics module performs object detection on the input image files based on a machine learning (ML) framework, such as TensorFlow® or PyTorch®.

The preferred embodiment of the present technology assigns a kitchen identification number or KIN to each kitchen related to a project or whose assets have been uploaded to the system. The KIN provides a universal identifier to the kitchens during the lifecycle of the project akin to a vehicle identification number or VIN. The same or related embodiment supports payments to the various stakeholders for sustainable goods and services or offerings provided via the platform. Such payments may be made in fiat or physical currency. Alternatively or in addition, these payments may also be made in a virtual currency, e.g. Bitcoin or Ethereum.

In the same or a related embodiment, the SGSE utilizes a cabinets database of the instant design. Such a database contains the dimensional relationships between the dimensions of a variety of cabinets and also preferably appliances, and the dimensions of the walls, floors and ceilings of a variety of shapes and sizes of kitchens.

Yet another embodiment utilizes an external integrations module that integrates or interfaces the instant SGSE with a variety of external entities using their respective application programming interface (APIs). Such external or 3^{rd} party entities include non-governmental organizations (NGOs), tax authorities, payment processors, manufacturers/suppliers, among others.

Clearly, the systems and methods of the invention find many advantageous embodiments. The details of the invention, including its preferred embodiments, are presented in the below detailed description with reference to the appended drawing figures.

### BRIEF DESCRIPTION OF THE DRAWING FIGURES

FIG. 1 highlights the difficulties and missed opportunities in the existing donation process of the prior art.

FIG. 2 illustrates the main embodiments of a sustainability goods and services exchange (SGSE) operating in an environment as based on the instant principles.

FIG. 3 shows a workflow or steps performed during the operation of the instant SGSE of FIG. 2.

FIG. 4 provides a technical architecture of a “tech stack” of the preferred embodiment of an instant SGSE.

FIG. 5 provides a high-level workflow, showing the functions performed by the various users and systems of the present technology in Capture, Create and Collaborate swim lanes.

FIG. 6A-B together show a circular economy workflow afforded by an instant SGSE, such as the SGSE of FIG. 2-4.

FIG. 7A shows a picture of a kitchen scene being captured via a mobile homeowner application of the present design.

FIG. 7B presents a screenshot from an exemplary implementation showing a kitchen scene being analyzed using the computer vision and AI techniques of the present teachings.

FIG. 8 shows an existing kitchen scene being analyzed to identify a hot region (for a cooking range), a wet region (for a sink) and a cold region (for a refrigerator) in the kitchen.

FIG. 9 shows a kitchen scene being analyzed for measuring the dimensions of the room, appliances and its cabinetry.

FIG. 10 shows the reconstruction of an as-is kitchen by an instant 3D reconstruction module and a digital twin service.

FIG. 11 shows an exemplary BOM or items list report referred to as a kitchen plan summary report generated by the instant platform.

FIG. 12 shows an excerpt from a cabinets database of the present principles.

FIG. 13 provides an exemplary visual representation of the dimensional relationships specified in an instant cabinets database.

FIG. 14 provides another exemplary visual representation of the dimensional relationships specified in an instant cabinets database.

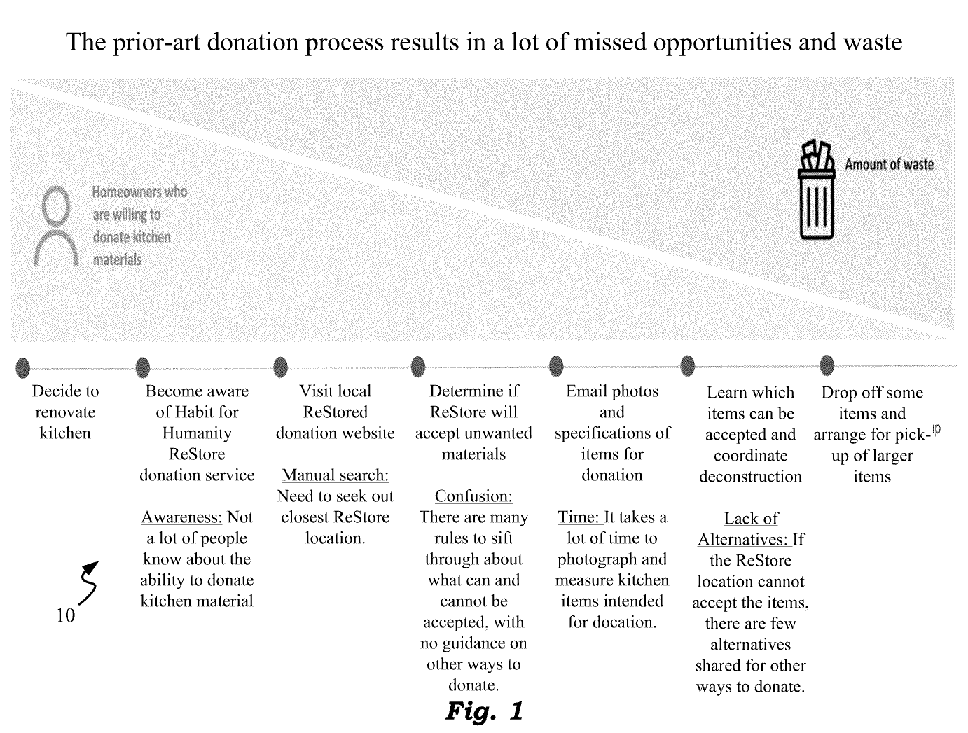

### DETAILED DESCRIPTION

The figures and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable, similar or like reference numbers may be used in the figures and may indicate similar or like functionality. The figures depict embodiments of the present invention for purposes of illustration only. One skilled in the art will readily recognize from the following description that alternative embodiments of the structures and methods illustrated herein may be employed without departing from the principles of the invention described herein.

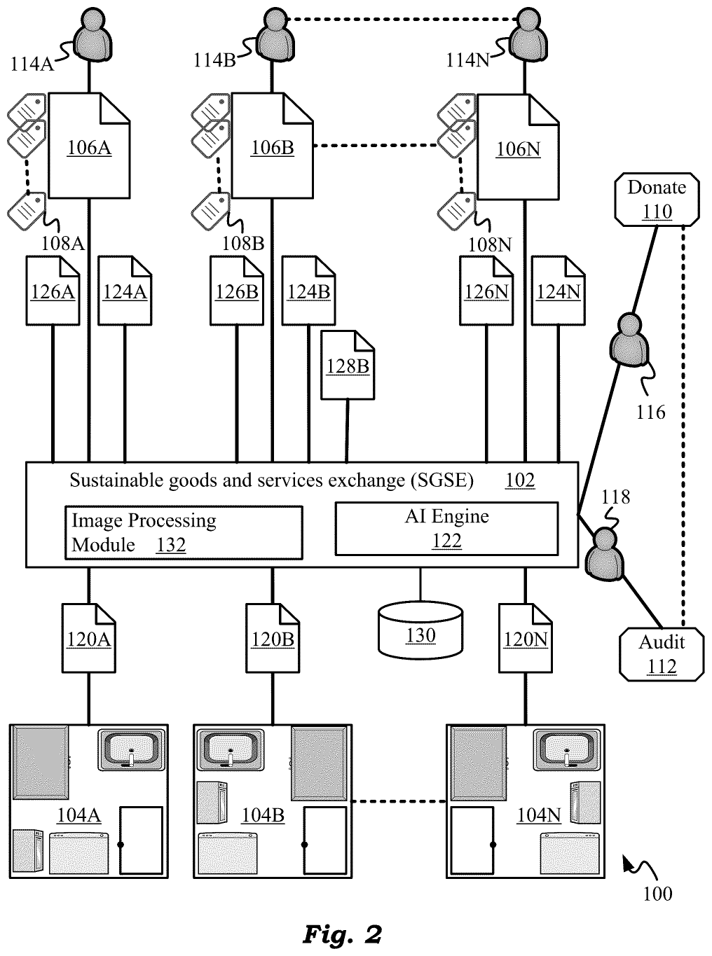

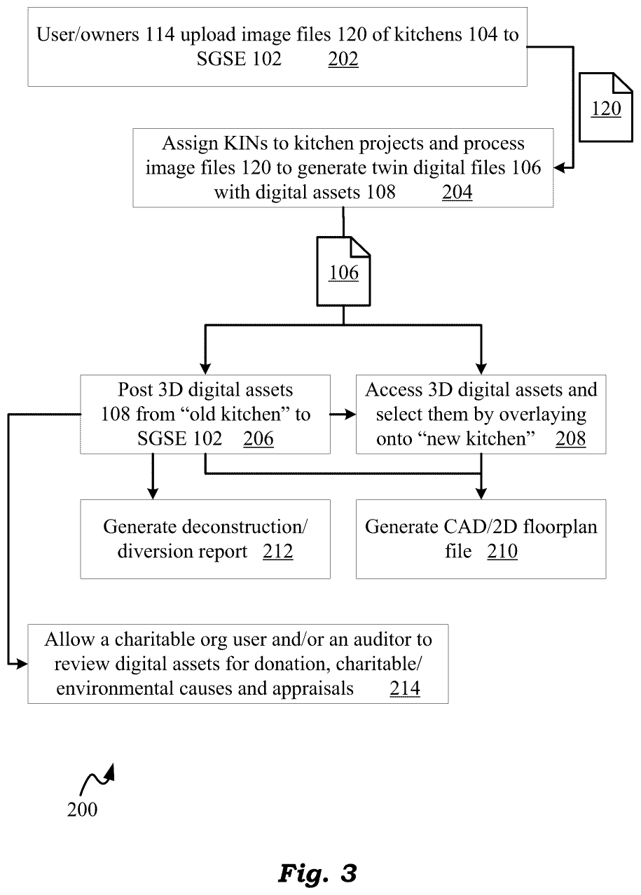

The present disclosure includes systems and methods for building and operating a circular or sustainable goods and services exchange or marketplace or platform 102 operating in an environment 100 as shown in FIG. 2. Such a sustainable goods and services exchange (SGSE) is used to provide sustainable construction offerings to the kitchen renovation industry based on the instant principles. Let us now review FIG. 2 which provides the design/structure of SGSE 102 with an along environment/framework 100 in which it operates. Let us perform this review in conjunction with workflow 200 shown in FIG. 3 that provides the technological steps of the operation of SGSE 102 in environment 100.

Exchange/platform 102 may be built as a web application or as a standalone application within the scope of the present principles. The application may be a desktop application and/or a mobile application running on a mobile computing device, such as a tablet or a smartphone or the like. Moreover, circular/sustainable technology platform/exchange/marketplace 102 is brand-agnostic. In other words, instant platform 102 is not confined to a specific brand or a manufacturer of kitchen products or assets. Such products/assets include cabinets, sinks and appliances. On the contrary, platform 102 is designed to attract participants from across the industry for accruing its various benefits as taught herein.

According to the chief aspects, there are one or more kitchens of various configurations designated by reference numerals 104A, 104B, . . . 104N as shown. These kitchens belong to their respective properties that are not specifically shown in FIG. 2 but are presumed to exist. Kitchens 104 have kitchen appliances and cabinets/cabinetry therein as shown. It is likely, though not required, that each of these kitchens has its own unique layout. Respective properties that kitchens 104A, 104B, . . . 104N belong to, are owned by property owners 114A, 114B, . . . 114N respectively. The properties that kitchens 104 belong to are primarily residential properties but they may also be non-residential or commercial properties within the scope of the present principles. As such, we may also refer to property owners 114 as homeowners in this disclosure. Based on the instant principles, property owners or homeowners 114 are also users of SGSE 102 as taught herein.

There are image files 120A, 120B, . . . 120N generated by respective property owners 114A, 114B, . . . 114N as a result of data capture or scan of their respective kitchens 104A, 104B, . . . 104N. These files are uploaded to SGSE 102. This first step is shown by process/box 202 in workflow 200 of FIG. 3. Any number of files 120, property owners 114 and kitchens 104 may be supported by platform 102. Exemplarily, each of image files 120A-N, e.g. file 120A may be a static/still image file, e.g. a gif, a jpeg, a png file among others. Image file 120A may also be a video file, such as an mpg or an avi file.

Regardless, image files 120, e.g. file 120A, contains the media content captured with the aid of an appropriate imaging system or a device such as a digital camera. File 120A may also be an mjpeg file containing a series of jpeg images of kitchen 104A taken by the camera. Depending on the embodiment, the digital camera may be housed in a smartphone, tablet, smartwatch or any other appropriate computing device, and which may or may not be a wearable device.

These image or input files 120A-N are then processed by an image processing module 132 of SGSE 102. Module 132 works in conjunction with an artificial intelligence (AI) module/engine 122 as shown. In alternative embodiments, image processing module 132 may comprise AI module/engine 122. Regardless, as a key feature of the present design, a kitchen identification number (KIN) is assigned to each kitchen project with each kitchen image file 120 that is uploaded to exchange/platform 102. In a manner analogous to a vehicle identification number (VIN), a KIN provides a universal identifier by which to refer directly to the kitchen and indirectly to the project in general, throughout the duration of the kitchen renovation project.

AI engine 122 utilizes a variety of AI techniques in order to process the input scene captured in files 120. These AI techniques will be discussed further below. Moreover, the various submodules/subsystems/modules/systems of SGSE 102 will also be discussed in detail further below. Further, computer vision techniques may also be utilized by image processing module 132 for processing input files 120, as and if required. When it is done with processing an input file, e.g. image file 120A, SGSE 102 produces a three-dimensional (3D) model or a 3D digital twin file or simply a digital file 106A of kitchen 104A. 3D model or 3D digital twin file 106A is a digital representation of kitchen 104A and contains 3D digital assets or artifacts or components 108A corresponding to the physical assets/artifacts/components, such as appliances and cabinetry within kitchen 104A. Similarly, SGSE 102 produces 3D digital twin files for kitchens 104B-N whose image files 120B-N have been uploaded into the system.

In the preferred embodiment, platform 102 also consults a cabinets database in order to accomplish its objectives. Such a cabinets database 130 shown in FIG. 2 contains the dimensions of the aforementioned kitchen assets/artifacts/components i.e. its cabinets and appliances, with respect to the dimensions of the walls, floors and ceiling of the kitchen. Explained further, since the dimensional relationships between the various sides/edges of the assets and their surroundings i.e. walls, floors and ceilings of kitchen 104A-N are known and stored in instant cabinets database 130, this facilitates the generation of corresponding 3D digital twin files 106A-N by image processing module 132 and AI engine 122. Appendix A provides an excerpt of instant cabinets database 130 that is consulted by instant exchange/platform 102 for this purpose.

The above process/step of assigning KINs to the kitchens and the treatment/processing of image files 120A-N by SGSE 102, and specifically by its modules 132/122 per above, to produce corresponding 3D digital twin files 106A-N, is shown by process/box 204 in FIG. 3. Now, each digital twin file or digital file 106A-N of kitchens 104A-N respectively can be referenced by the KIN assigned to the corresponding kitchen in system 102. In other words, 3D digital twin file for kitchen 104A can be referenced by the KIN assigned to kitchen 104A by SGSE 102. Preferably, a KIN is a numeric or alphanumeric serial number, e.g. 101, 1456X7r, etc.

As mentioned, property owners 114A-N are also users of SGSE 102. At this stage in workflow 200, property owners 114 have the option of uploading 3D digital assets 108 as digital inventory onto instant platform 102 so that it becomes available for reuse/recycling by other property owners as shown by step 206. Property owners, e.g. property owner/user 114B, who is interested in reusing these 3D digital assets can now access these 3D digital assets inventory in exchange/platform 102. They can then overlay/place these digital assets over their kitchen scene of kitchen 104B using a graphical user interface (GUI) or user experience (UX) provided by platform 102. For this purpose, augmented reality (AR) and/or virtual reality (VR) techniques may be employed. This is shown by process step/box 208 in workflow 200 of FIG. 3.

The preferred embodiment of the present technology uses a “freemium” pricing model in which users are able to upload their digital assets inventory for free so as to promote reuse of kitchen assets/artifacts that would otherwise be discarded. However, for reusing and accessing inventory, they may be required to pay, exemplarily via a subscription model. Therefore, in the preferred embodiment, user 114A who is posting their old kitchen inventory onto platform 102 will be a free user of the system. On the other hand, user 114B who is interested in reusing the inventory posted onto platform 102 by other users, e.g. user 114A, will be a paid subscriber.

Once user 114B of our above example is satisfied by the new look/layout of their kitchen or simply their “new kitchen”, they can instruct platform 102 to generate a computer-aided design (CAD) file 124B of their new kitchen. File 124B may also be or contain a 2D floor plan or have any suitable format that can be consumed by a contractor or tradesman in order to produce an estimate and/or install the new kitchen for user 114B. Thus, SGSE 102 generates CAD or 2D floor plan files 124A, 124B, . . . 124N respectively for each of kitchen 104A, 104B, . . . 104N as shown. In the preferred embodiment, the quote/estimate and bidding, contract approval and project management of the “job” is kept external to SGSE 102. However, alternate embodiments extend SGSE 102 to provide these capabilities through instant platform 102 itself.

Now, continuing with our example above, property owner/user 114A may just be interested in posting or uploading digital assets 108A of their “old kitchen” to platform 102. In other words, they may be in reusing not interested any other digital assets/artifacts 108B-N warehoused in platform or marketplace 102 for themselves or for their old/existing kitchen 104A. However, they may still generate a CAD or 2D floor plan file 124A via system 102 in order for a contractor/tradesman to perform deconstruction or demolition services for their old kitchen. They may then install new kitchen assets in their kitchen externally to platform 102. The step of generating a CAD file or a 2D floorplan of any suitable file consumable by a construction/deconstruction contractor/tradesman for an instant kitchen project is shown by step/box 210 in workflow 200.

As a key benefit of the present technology, platform 102 can also automatically generate a deconstruction or diversion report 126A for user 114A for their old kitchen, which the user can provide to an appropriate government agency or authority for building permits. Such an agency/authority may or may not be local. Each property owner 114A, 114B, . . . 114N can generate respective deconstruction/diversion reports 126A, 126B, . . . 126N based on the instant technology. This step is shown by process/box 212 in workflow 200 of FIG. 3.

As another benefit of the present design, user 114B of our above example can also generate a list of digital and corresponding physical assets akin to a bill-of-materials (BOM) 128B for their new kitchen. Instant system 102 can generate such a BOM/list 128B because it has information about all the components/assets and materials required for the project based on the digital twin file 106B and CAD file 124B. BOM/assets list 128B also provides the data needed to estimate budget/cost information for all the components/materials required for the project. Note that not all owners/users, exemplarily owner 114A who is only posting kitchen assets to the platform, may need and generate such a BOM/list for their project. BOM/assets list file 128 is thus not shown for every owner/user 114 in FIG. 2.

Let us now understand that there are three types of kitchen renovation projects as discussed further below. A “Replacement” project, also sometimes referred to as a “full gut” replaces all the assets of a kitchen with reused/pre-owned/used assets uploaded/warehoused in SGSE 102. A “Refacing” project includes a combination of resurfacing/refurbishing and replacement of the kitchen assets. A “Resurfacing” project includes only resurfacing/refurbishing of the cabinets while some of the other components may be replaced. SGSE 102 is used in the pre-construction, planning and design phase by the homeowner in order to understand the above three project options. Specifically, the SGSE enables the homeowner to estimate the cost of each project option and the impact it will have in terms of sustainability, such its carbon footprint.

Instant SGSE 102 of FIG. 2-4 facilitates all of the above types of renovation projects. The ability to generate a BOM or assets/materials list and also preferably the estimated cost of a kitchen renovation project by a property owner/user facilitates the matching of an appropriate tradesman/contractor with the project. Even for Refacing and Resurfacing projects, property owners and tradesmen benefit from the instant platform by having access to the BOM or assets list for the kitchen. A contractor/tradesman can thus accurately assess the requirements of a given job, whether it requires servicing/refurbishing or replacement or both.

It will be evident that as a consequence of the above design and operation of present SGSE/platform 102, construction and demolition (C&D) waste related to kitchen (projects) 104A-N is minimized. This is because old kitchen assets/artifacts are put to reuse on platform 102 by their respective owners 114, e.g. owner/user 114A of the above example. As a consequence of their action, user 114A may also get monetary benefits such as tax benefits/deductions. Besides, they are at least participating in reducing the amount of discarded waste in alignment with the principles of a circular economy.

Furthermore, owners/users 114, e.g. owner/user 114B who are interested in reusing the old assets, can find/access them on instant platform 102 and install/use them. They can thus benefit monetarily by obtaining the assets for their new kitchen at low or no cost. They also participate in reducing discarded waste and in the circularity of the economy. In some embodiments, property owner 114B of our above example may even pay directly to property owner 114A, from within or externally to platform 102, for the reused assets of old kitchen 104A. Similarly, property owners 114A-B of the above example, may pay their tradesmen from within or externally to platform 102. In order to facilitate payments to the stakeholders from within SGSE 102, a payment gateway is preferably provided, as will be discussed further below. Such a payment gateway can facilitate the above payments in either fiat currency or virtual currency/digital tokens.

The monetary benefits to the stakeholders provide additional incentive for reuse/recycling or circularity in the present design. The system can thus scale rapidly to create a network effect whereby more users/owners 114 are attracted to marketplace 102 because there is more used inventory in it. Instant platform 102 also acts as a central hub for all communication as well as a central repository for all documentation of projects for all concerned stakeholders. This facilitates better communication and collaboration between the stakeholders and less friction as compared to the practices of the prevailing art.

Furthermore, as shown in FIG. 2, there are also user(s) 116 belonging to a charity/charitable or a non-profit or an environmental cause organization or organizations 110. A charity organization 110 can also participate in the circular benefits of the present technology. More specifically, user 116 can access the posted digital inventory on platform 102 and acquire it for reuse/reselling for a charitable or environmental cause. In return, corresponding property owners 114 whose digital assets were used can get rewarded with tax benefits or even receive direct monetary compensation.

There are also user(s)/appraisers(s) or assessor(s) 118 belonging to an independent deconstruction appraisal agency or company 112. Deconstruction appraisal company 112 can audit the digital goods on platform/exchange 102 and estimate/appraise their value independently or in concert with charity/donation agency 110. The appraiser/assessor is also in charge of preparing the required documentation for tax deduction/benefits for property owners 114 of respective digital goods 108. Depending on the embodiment, organization(s) 110 and 112 may be the same, and consequently user(s) 116 and 118 may also be the same or belong to the same organization. The above process of achieving further circularity in the present design by benefiting one or more charitable/donation organizations is shown by process/box 214 in FIG. 3.

The present technology thus valorizes kitchen C&D waste from kitchen renovation projects by allowing otherwise discarded physical assets/products to get a “second life” in a new kitchen. Moreover, aside from processing input image files 120 of kitchens 104, further AI techniques may also be employed. For example, and while continuing with our above example, SGSE 102 may employ additional AI techniques to facilitate the “fitting” of digital assets. These digital assets include assets 108A of old kitchen 104A of property owner 114A in particular, and any other assets 108 in general, including assets 108B posted by property owner 114B for reintegration into their new kitchen 104B.

The above assets are overlaid and fitted onto kitchen 104B by property owner 114B. In such a manner, the AI techniques can optimize the usage of kitchen 104B in its home/property and produce bespoke digital twin and CAD files 106B and 124B respectively, given the specific shape, size and other characteristics of kitchen 104B. This additional capability of the present design generates further secondary market value, operational efficiency and circular innovation.

As a result of the circular attributes and the many related benefits accrued by the present technology, a variety of ESG (Environmental, Social and Governance) initiatives are facilitated. Such initiatives aim to minimize environmental footprint by promoting sustainable practices through waste reduction, generally in the construction industry and particularly in the kitchen remodeling industry. Still additional benefits for industry participants as a result of instant platform 102 of the above teachings are given below.
1. For businesses: Customer data related to users 114 stored in platform 102 can be used for lead generation for business stakeholders such as tradesmen and contractors.
2. For the industry: Customer and project data in the platform can also be used to create standards and secondary market opportunities.
3. For the government: Project data in platform 102 can be used for measurement, reporting, verification and standardization of carbon data in construction materials. This data can also be used to inform and enforce government regulations on the industry.

In other embodiments, an instant SGSE is integrated with construction goods manufacturers/suppliers for automatically downloading the 3D digital files of kitchen assets and products produced by the manufacturers/suppliers. For this purpose, an external integration module may be employed that integrates with the manufacturers/suppliers using their respective application program interface (APIs).

In still other embodiments, rather than generating a digital twin file 106 as well as a CAD file 124, instant SGSE generates a single output file. Such a single output file contains the contents of a 3D digital model containing digital assets as well as those of a CAD file that can be used by a downstream tradesman or a contractor.

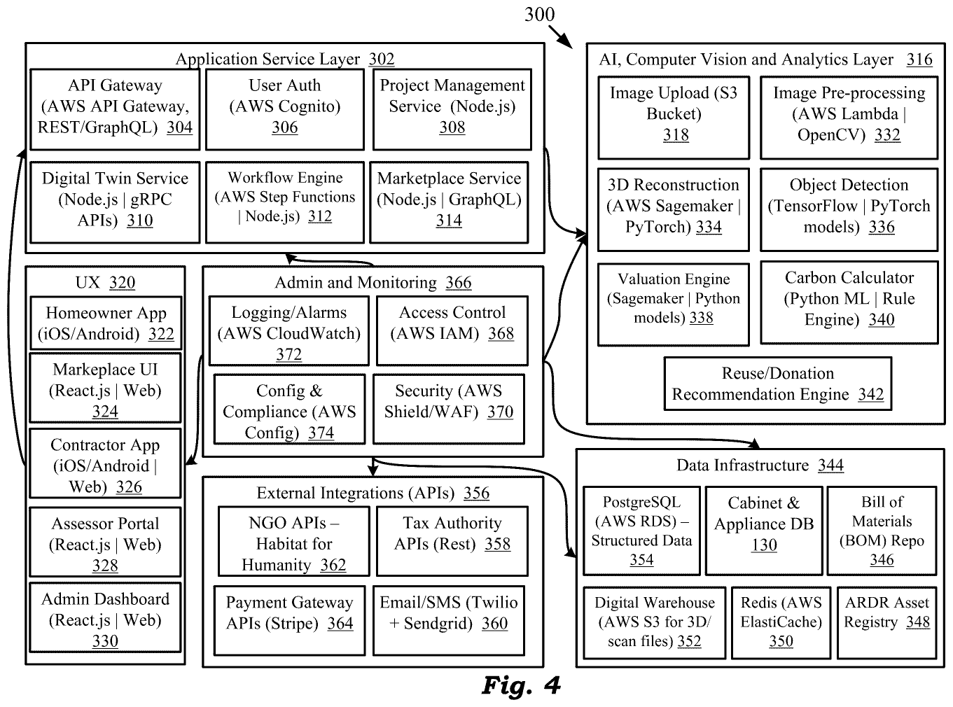

FIG. 4 presents an architectural diagram or a “tech stack” 300 of SGSE 102 of the above teachings from preferred implementation. The diagram shows the various architectural layers or modules or systems of SGSE 102, along with their respective computer applications or submodules or subsystems or simply modules or systems. The various technological choices, or other details for implementing the various modules are shown in parenthesis in tech stack 300. Let us now review FIG. 4 in conjunction with FIG. 2-4 of the above teachings.

There is a user interface or user experience (UX) layer or module 320 that provides the user interfaces (UIs) of various computer applications of SGSE 102. These include a homeowner application 322, a marketplace application/UI 324, a contractor application 326, an assessor portal 328 and an administration (admin) dashboard 330 as shown.

The functionality that these user interfaces provide for their respective intended users i.e. homeowner or property owner, contractors and assessor will be evident from the use-cases and examples of the above discussion. More specifically, homeowner application 322 provides the UI for property owners 114 of FIG. 2 to upload image files of their kitchens 104 to SGSE 102 and to perform a variety of functions as discussed above. These include accessing 3D digital twin files 106, 2D CAD files 124, diversion reports 126, BOM 128, overlaying and fitting kitchen assets 108 onto their respective kitchens 104, among others. Marketplace UI 324 is the UI for the marketplace functionality of SGSE 102 as discussed herein.

Among other functions, contractor application 326 enables contractors and tradesmen to access 2D CAD files 124, BOM 128, etc. As noted above, the stakeholders can identify a project and access its various files and data by using/entering the KIN(s) associated with the project. Assessor portal 328 allows users 116 and/or 118 of the above discussion to access digital kitchen assets 108 and to estimate/appraise their value. As also noted above, platform 102 includes the ability of its various users to send and receive payments for the goods and services rendered through the platform. Such payments may be in the form of physical or fiat as well as cyber/virtual currencies e.g. Bitcoin or Ethereum.

Admin dashboard application 330 provides the administrative and management functions required to maintain a stable operation of the system. Any of applications 322-330 may be desktop applications and/or mobile applications capable of operating on iOS® and Android™ or any other mobile platform operation system (OS).

There is also an application service layer 302, with an application programming interface (API) gateway 304. Gateway 304 may employ amazon web services (AWS®) API Gateway or GraphQL and/or another Representational State Transfer (REST) technology. There is also a user authentication/authorization module 306 responsible for authenticating and authorizing the users of the system. Module 306 is built using AWS Cognito in the preferred embodiment whose architecture is shown in FIG. 4. There is a project management service 308 responsible for providing project management functions of the kitchen renovation projects of the above teachings. Exemplarily, this service runs on a Node.js® environment.

There is also a digital twin service 310 responsible for generating digital twin files 106 of the above discussion, and exemplarily employing Node.js and gRPC APIs as shown. Workflow engine 312 is responsible for the overall workflow management of the various projects supported by SGSE 102. Exemplarily, module 312 employs AWS Step Functions and/or Node.js technologies. There is also a marketplace service 314 in application service module/layer 302 that works in conjunction with marketplace UI 324 of the above discussion and provides the marketplace capabilities for warehousing and buying/selling kitchen assets of the above discussion. Preferably, marketplace service 324 is built using Node.js and/or GraphQL technologies as shown in FIG. 4.

The architecture or tech stack of instant SGSE 102 of FIG. 2 also includes an artificial intelligence (AI), computer vision and analytics module or layer 316 as shown, and whose job is to impart various processing and analytical capabilities to the system. More specifically, an image upload submodule/subsystem/application 318 of module 316 is responsible for the uploading of image files 120 of FIG. 2 by users 114 into an AWS Simple Storage Service (S3) bucket. An image preprocessing application 332 is responsible for analyzing/processing image files 120, preferably using OpenCV vision library, and preferably on an AWS Lambda serverless architecture. There is a 3D reconstruction application 334 employing AI technologies that include AWS Sagemaker and/or PyTorch®. Module 334 works in conjunction with digital twin service 310 to produce digital twin files 106 that reconstruct the digital versions of kitchens 104. For this purpose, module 334 may employ one or both of AI and computer vision techniques.

Object detection module 336 is responsible for detecting assets/objects in the 3D scenes contained in image files 120 by leveraging machine learning frameworks including TensorFlow® and/or PyTorch®. Valuation engine 338 preferably built on AWS Sagemaker and/or Python® models works in conjunction with assessor portal 328 to estimate/establish the assessed/appraised values of kitchen assets by users 116/118. Carbon calculator 340 is preferably built using Python machine learning (ML) models and/or a rule engine. It is responsible for calculating the carbon offsets/credits associated with a given kitchen renovation project. There is also a reuse and/or donation recommendation engine 342 as shown that is responsible for providing recommendations to the user on reusing and donating the various kitchen assets related to the renovation projects supported by platform 102.

The tech stack of FIG. 4 of the preferred embodiment also includes a data infrastructure layer/module 344 with the responsibilities of storage and retrieval of data and for its flow and orchestration to and from various other system modules. In order to accomplish its objectives, data infrastructure layer 344 employs an AWS relational database service (RDS) for PostgreSQL 354 for the management of structured data. There is a digital warehouse 352 for storing project files including scanned 3D image files 120 of the projects in AWS S3 bucket(s). There is also a cabinet and appliance database 130 of the present teachings. There is a bill of materials (BOM) repository 346 for storing and generating BOMs per above teachings. There is an AWS Elasticache for Redis® for providing an ultrafast in-memory datastore 350 for our data infrastructure module 344. There is also an assets removed during renovation (ARDR) registry/repository 348 as shown for housing digital assets whose corresponding physical assets have been removed during a project.

The technical architecture of SGSE 102 of FIG. 2 also employs external integrations 356 as shown in FIG. 4. These are meant for integrating/interfacing the platform with external/3^{rd} parties. External integrations 356 include NGO APIs 362 for integrating with non-governmental organizations (NGOs), such as Habitat for Humanity. These also include Tax Authority APIs 358 for integrating with tax authorities, such as Internal Revenue Service (IRS). External integrations 356 also include payment gateway APIs 364 for interfacing with payment gateways or payment processing platforms, such as Stripe®. As noted herein, payment gateway 364 supports the payments of both fiat and virtual currencies in platform 102. There are further email/SMS APIs 360, preferably based on technologies such as Twilio® and Sendgrid® as shown.

The preferred tech stack 300 of FIG. 4 for our SGSE 102 of FIG. 2 also includes an administration and monitoring module 366 that works in conjunction with admin dashboard/UI 330 discussed above. Module 366 includes a logging/alarms submodule/module 372 responsible for providing monitoring, logging and alarm management functions of the system. Preferably, logging/alarms module 372 employs AWS CloudWatch and works in conjunction with module 360 to send alarm notifications via SMS and/or email.

Admin and monitoring module 366 manages access control to the system via access control module 368. Module 368 preferably employs AWS identity and access management (IAM) technology. There is a configuration and compliance management module 374 for managing configuration rules and for providing resource inventory, configuration history, and compliance auditing. Finally, there is a security module 370 for providing security for SGSE 102. Security module 370 preferably employs AWS Shield and AWS web application firewall (WAF) technologies to protect the platform against cyberattacks and to provide privacy of homeowner data.

Furthermore, the AI capabilities of SGSE 102, and specifically its AI, computer vision and analytics module 316 discussed above in reference to FIG. 4, include the following:
1. Screen capture and recognition for generating 3D digital twin file 106 from scanned and uploaded scenes/files 120.
   a. Computer Vision Processing:
      i. Extracts structural elements from the scene e.g. walls, floors and ceiling boundaries.
      ii. Identifies kitchen components, including cabinets, appliances, countertops and fixtures. Further, algorithmically identifies hot, cold and wet areas.
   b. 3D digital twin file 106 generation.
      i. Convert videos and 2D photos in files 120 into a spatially accurate 3D kitchen layout.
      ii. Assign a unique KIN to each kitchen in the system associated with a kitchen renovation project.
   c. Asset inventory extraction.
      i. Auto-detect material composition i.e. whether wood, stone, medium-density fiberboard (MDF) among others.
      ii. Extract dimensional metadata e.g. 36 inch cabinet, 8 foot ceiling, etc.
2. Asset valuation and ARDR candidate identification (ARDR candidates)
   a. Asset recognition and classification
      i. Identifies reusable items, such as cabinets, doors, countertops, and hardware.
      ii. Match detected components against cabinets database 130.
   b. AI-driven condition and quality assessment
      i. Uses image features e.g. scratches, wear and finish to assess condition.
      ii. Flags items as candidates for ARDR (assets removed during renovation).
   c. Valuation engine based on AI and market data
      i. Predicts resale value using resale marketplaces, depreciation models and comparables.
      ii. Supports human assessors with suggested price ranges for each item.
3. Asset intelligence and tagging
   a. Automated BOM creation
      i. Generates BOM with accurate sizes, quantities and material specifications.
   b. Smart tagging
      i. Apply metadata such as material type, (e.g. MDF, plywood, quartz), quality descriptions (e.g. “good”, “pine or better’), and functional attribut8es (e.g. doors, shelves, drawers).
   c. Digital warehouse integration
      i. Stores tagged assets for retrieval, reuse, resale, or marketplace listing.
4. Sustainability and circular optimization
   a. Carbon and ESG analysis
      i. Estimates embodied carbon, compares reuse versus disposal, and creates diversion and compliance reports.
   b. Circular pathway recommendations.
      i. Based on AI models, recommends reuse, resale, donation (e.g. Habitat for Humanity), or recycling based on asset demand and sustainability impact.

Table 1 below presents the functions performed by the various users and systems of SGSE or platform 102 of the above discussion, in 3 swim lanes: Capture, Create and Collaborate.

TABLE 1

| CAPTURE (Input) | CREATE | COLLABORATE (Output) |
|---|---|---|
| 1. Homeowners | 1. Using CAD file 124 | 1. Platform 102 |
| capture the | generated from | provides an integrated |
| existing | Capture, the platform | tool for collaboration |
| kitchen scene | configurator works | throughout the |
| using standard | in conjunction with | lifecycle of the |
| mobile phone | cabinets database | renovation project. |
| camera scanning | 130 of 3000+ | a) homeowner and |
| capabilities | cabinet models to | project trade |
| via Homeowner | create a to-be | professionals |
| App 322. The | virtual 3D digital | (contractors, |
| information is | twin of the scene | designers, |
| received into | to include | suppliers, |
| SGSE/platform | a. room dimensions | secondary market |
| 102 of FIG. 2. | b. material list of | vendors/salvage |
| Users 114 do | digital assets | organizations, |
| not need to be | (cabinets, appliances, | appraisers) |
| technologically | etc.) | collaborate to |
| savvy to | AI agents and/or | manage the project |
| complete this | gaming technology | via SGSE/platform |
| task. | may also be utilized | 102. |
| 2. By utilizing | for this purpose. | b) CPA/accountant |
| AI/ML and | Database 130 of 3000+ | and appraisers for |
| Computer | cabinets (also called | those homeowners |
| Vision | the 1 × 3 system) includes | that qualify for |
| technologies, | models that are | tax deduction |
| Computer | specifically used for a | credit of donation |
| Vision And | residential kitchen | property valued |
| Analytics | based on elevations | at more than |
| module 316 in | (height, width, depth) | $50,000 of kitchen |
| conjunction | and kitchen standards/ | components (IRS |
| with digital | building codes. | Form 8283 Noncash |
| twin service | 2. A Kitchen ID# (KIN) | Charitable |
| 320, the | is created and assigned | Contribution) |
| platform is | to the kitchen | c. B2B |
| able to detect | associated with the | collaboration |
| and | project. A link to the | 1. Creation of |
| reconstruct an | portal and project can | Industry standards |
| as-is digital | be shared with all | 2. Connecting |
| twin/version | stakeholders working on | contractors and |
| of the space | the project in platform | designers with |
| and components | 102. The KIN# is used to | secondary market |
| from the scan. | collect, retain and | vendors |
| The output is | distribute all input | (sell or donate) |
| a 3D digital | project data/information | d. Collaboration |
| twin file 106 | and output reports | with government |
| per above | digitally. | SGSE/platform |
| teachings. | 3. Digital Warehouse - | 102 provides data, |
| 3. Platform 102 | components of existing | (e.g. used green |
| is thus able to | kitchens are warehoused | card data/ |
| detect unique | digitally on instant | Leadership in |
| components of | platform 102. The | Energy and |
| the scene in | Platform includes a | Environmental |
| order to | Visualizer/Editor that | Design (LEED ®) |
| accurately | be used to redesign | points) that can |
| detect the | space or reintegrate | be provided to |
| various | existing components | all stakeholders |
| regions in the | into a different kitchen | in order to |
| kitchen i.e. | e.g. kitchen 104B in the | encourage and |
| “hot” for the | example discussed in | measure the |
| range, “wet” for | reference to FIG. 2, by | transition from |
| the sink and | matching room | linear economy to |
| “cold” for the | specifications with | circular economy. |
| refrigerator. | digital assets in the | 2. Automated reports |
| 4. A single CAD | warehouse. | a. 3-level options and |
| file 124 is | 5. Blockchain ledger. | budget reports for |
| generated that | Smart contracts for | homeowners. These |
| contains all of | cryptographically | are the three |
| the pertinent | securing all | options of kitchen |
| information | transactions/interactions | renovation projects: |
| from the scene | between the | Resurface/Refurbish, |
| (e.g. objects, | stakeholders without | Reface and Replace, |
| dimensions, | the need for | along with their |
| weight, | intermediaries. | estimated costs and |
| deconstruction | 6. Platform configurator/ | the impact each will |
| materials and | calculator or simply | have in terms of |
| debris | configurator/calculator | sustainability, such |
| calculations). | provides the appraiser | as the carbon |
| The file is | with the data and | footprint of each |
| exported to a | estimated values unique | type of project. |
| platform | to the building material | b. Homeowner diversion |
| configurator in | and components that can | reports 126. |
| a preferred | be used by the appraiser | i. Environmental |
| embodiment. | to determine the final | product declarations |
| | valuation to accountant | ii. Includes industry |
| | for tax deduction/ | standards (e.g. |
| | credit purposes. | Residential Energy |
| | | Services Network |
| | | (RESNET 1550)) |
| | | standards for |
| | | calculating and |
| | | reporting embodied |
| | | carbon of homes |
| | | and Global Warning |
| | | Predictor (GWP). |
| | | c. Digital asset list. |
| | | Appraisers can use |
| | | this to establish |
| | | the estimated value |
| | | of a kitchen if |
| | | being donated. |
| | | 3. Output reports are also |
| | | provided to government |
| | | agencies to track reused |
| | | materials that meet |
| | | RESNET 1550 Standards |
| | | for embodied carbon |
| | | emissions. |

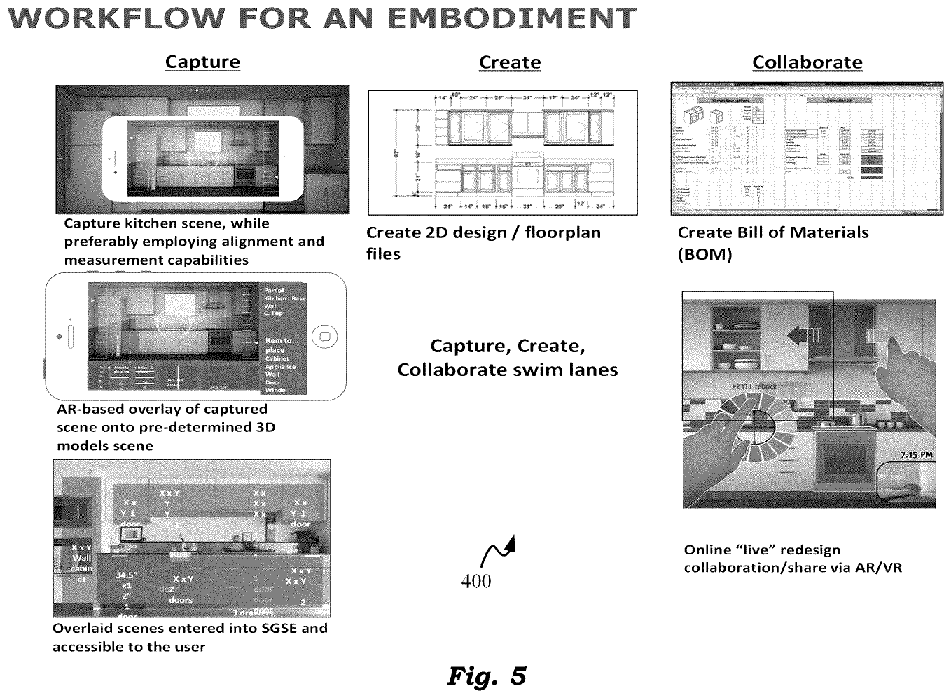

In conformance with Table 1, FIG. 5 provides a high-level workflow 400, showing the functions performed by the various users and systems of the present technology in Capture, Create and Collaborate swim lanes.

The main distinguishing features of an instant sustainable goods and services exchange, such as SGSE 102 of FIG. 2-4, include the following:
1. Educates/informs users about sustainable kitchen renovation options and provide the steps and reports that encourage various actions for the users. These include reuse, refurbishing and/or reintegration of the components of an existing kitchen, e.g. kitchen 104A of the example discussed in reference to FIG. 2 above, in order to give them a second life. System 102 provides a digital exchange/warehouse via modules 314, 324 and 352 discussed above, for matching pre-owned kitchen assets or materials, prior to deconstruction, with a new kitchen e.g. kitchen 104B of the example discussed in reference to FIG. 2 above. By connecting property owners or consumers with businesses that specialize in refurbishing or recycling kitchen assets, the platform extends the life of products and reduces waste.
2. Educates homeowners about 3 renovation options for them to be able to make informed decisions.
   a. Resurface/Refurbish (difficulty: minor)—resurface/refurbish cabinet doors and drawers, countertops, appliances (new burners) and floors.
   b. Reface (difficulty: medium)—combination of resurfacing/refurbishing and replacing cabinets, countertops, appliances and flooring. Historically, 90% of countertops are replaced.
   c. Replace (difficulty: major)—completely gut and replace all components of a kitchen.
3. Provides BOM/lists of components 128 and associated data needed for each type of renovation list above under 2(a), 2(b) and/or 2(c) above to be provided to the project stakeholders.
4. Creates digital assets warehouse 352 and a discovery engine, leveraging data and algorithms to help homeowners find pre-owned kitchen components that meet their specific needs. Instant platform preferably uses blockchain and smart contracts to secure the transactions/interactions between the participants.
5. Provides assurance and standards: To build trust in the quality of pre-owned kitchen materials, instant platform implements rigorous testing and certification processes. This assurance alleviates concerns associated with second-hand purchases, making sustainable options more appealing to homeowners.
6. Provides standardized processes and procedures for listing, communication, data needed to estimate pricing, and compliance with regulations.
7. Facilitates the donation and tax credit process for kitchen materials. By creating a marketplace for refurbished cabinets, appliances, and other components, instant platform extends the lifespan of these products and reduces the need for new manufacturing.
8. Handles complex logistics of collecting, storing, and delivering pre-owned kitchen material.
9. Data—Instant platform analyzes and classifies data and metadata stored in it. It can then derive benefits for the following participants:
   a. Businesses—Customer/consumer and project data analytics can be used for lead generation. Further, appraisers who need industry data in order to provide accurate appraisals for donation process can also benefit from the analytics.
   b. Industry—data can be used to create needed industry standards and inform the development of new products and services that align with circular economy principles.
   c. Government—stored data can be used to measure and verify the embodied carbon in construction materials. This can inform and enforce government regulations.
10. Automatically collect data (input)—reduces time and errors.
11. Create reports to manage entire lifecycle of renovation project (output).
12. Allow multiple users to access project information in real-time in order to collaborate and manage the project effectively and efficiently.
13. Reduces friction:
   a. Improves customer experience.
   b. Enables collaboration between stakeholders. Instant SGSE utilizes virtual design and construction (VDC) principles for significantly improving the productivity and user experience of various stakeholders in kitchen renovation projects. VDC blends the physical and digital worlds by utilizing computer vision (CV) and augmented reality (AR) techniques and/or virtual reality (VR) techniques.

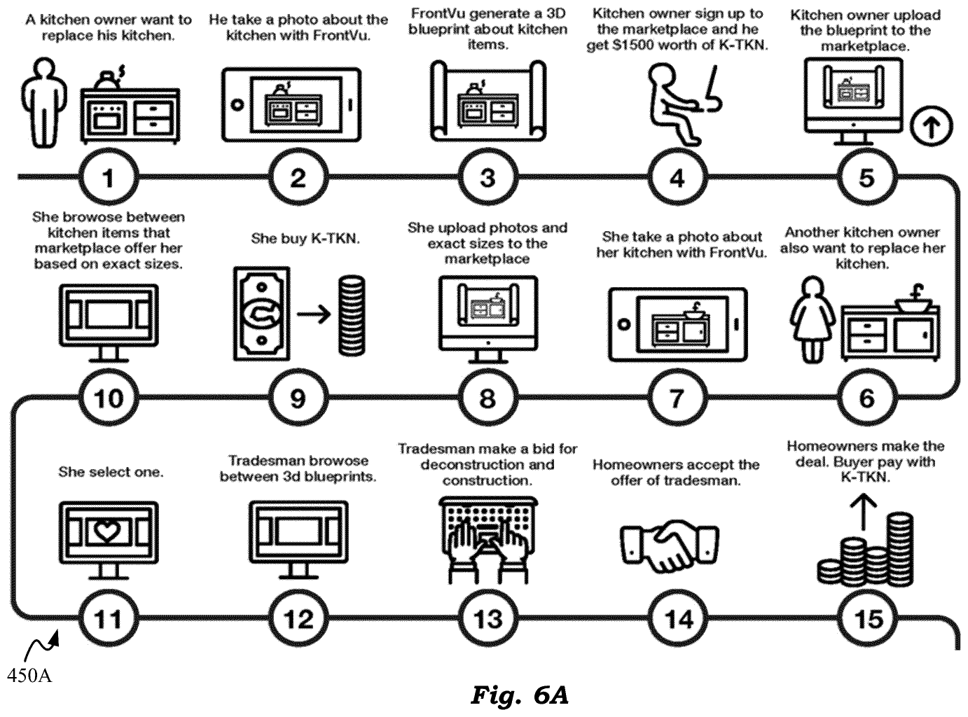

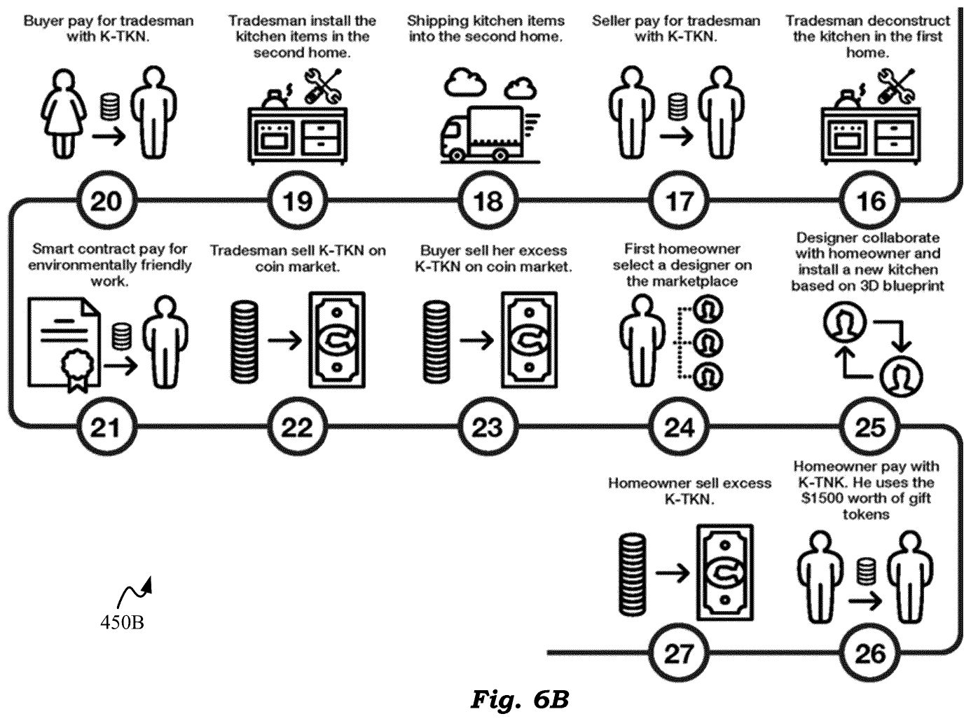

FIG. 6A and FIG. 6B show circular economy workflows 450A and 450B as afforded by an instant SGSE, such as SGSE 102 of FIG. 2-4 of the above teachings. Workflow 450B is a continuation of workflow 450A. As shown, the instant SGSE support payments to the various stakeholders not only in the form of fiat currency but also in the form of virtual tokens, or cryptocurrencies e.g. tokens K-TKNs shown in FIG. 6A-B.

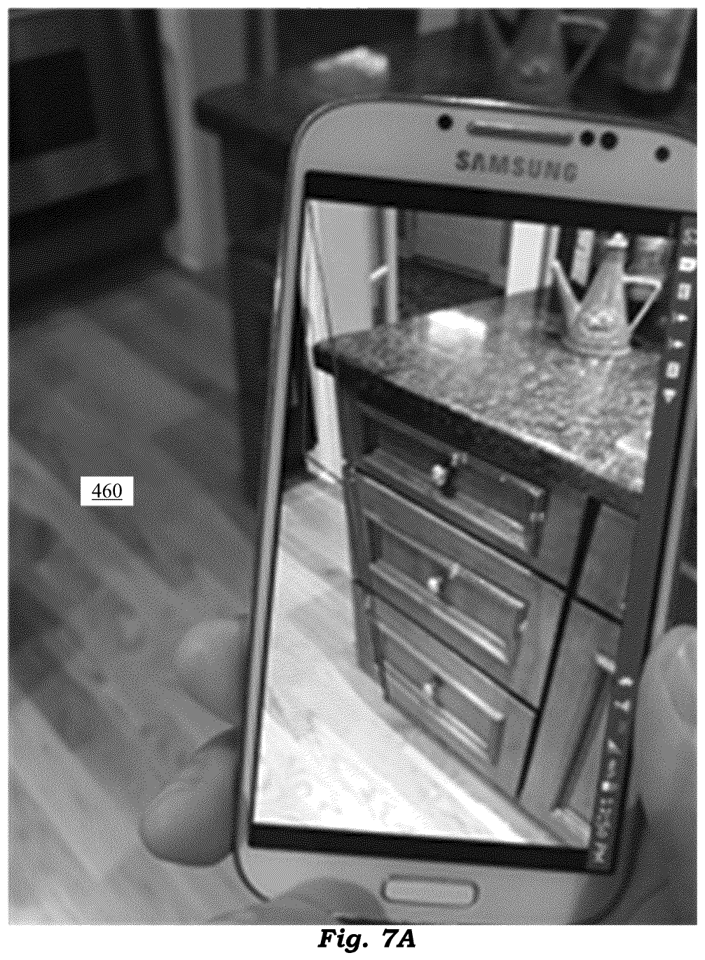

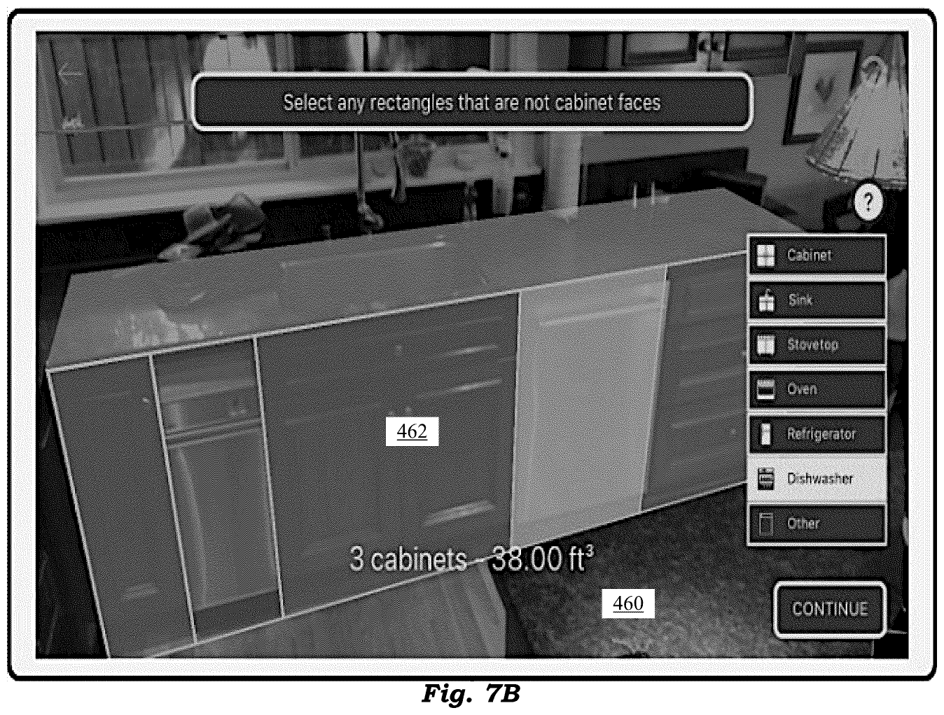

FIG. 7A shows a photograph 460 of a kitchen scene being captured via a mobile homeowner application 322 of the above discussion. FIG. 7B is a screenshot from an exemplary implementation showing a kitchen scene being analyzed using the computer vision and AI techniques of the present teachings. More specifically, FIG. 7B shows how 3D scene 460 is analyzed using AI, computer vision and analytics module 316 of the above teachings. It shows that based on the analysis, 3 cabinets 462 of 38 ft3 total volume are identified.

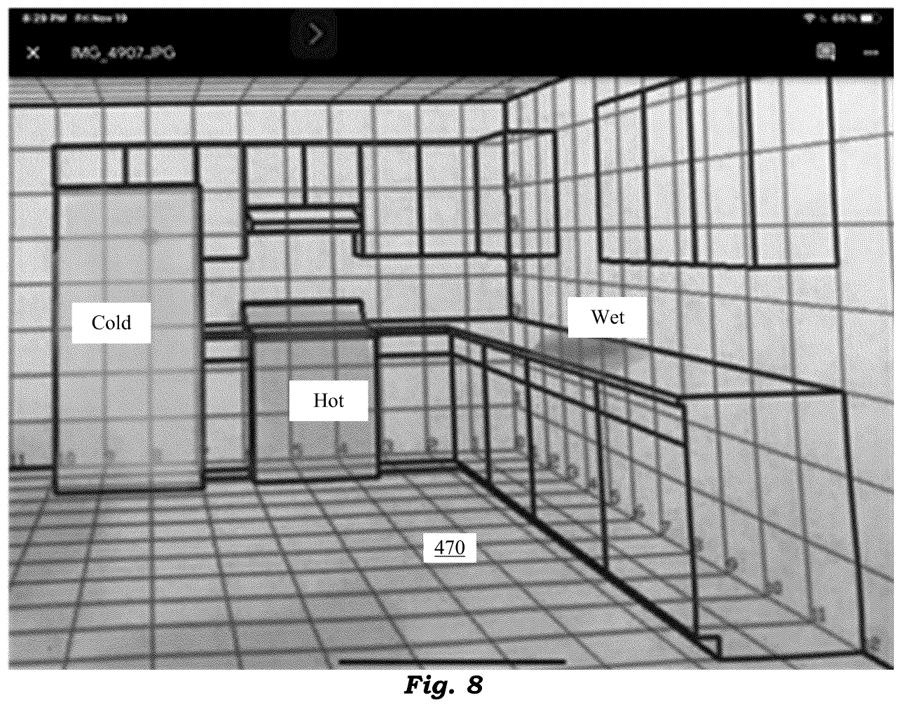

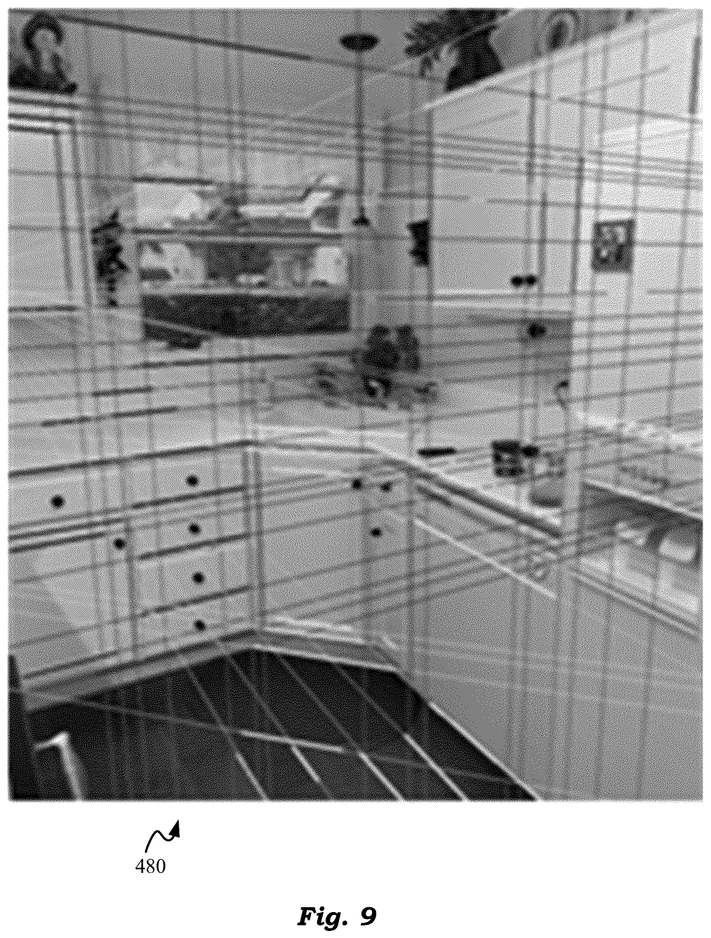

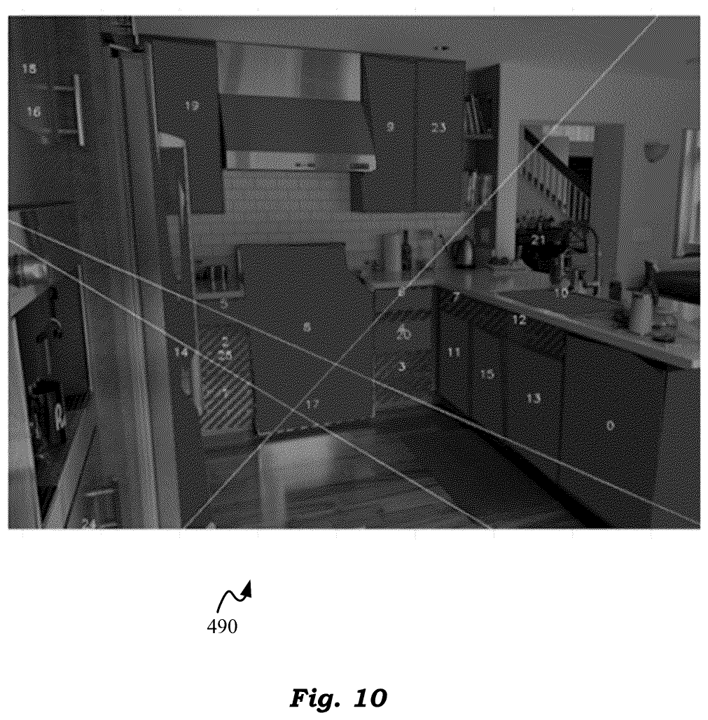

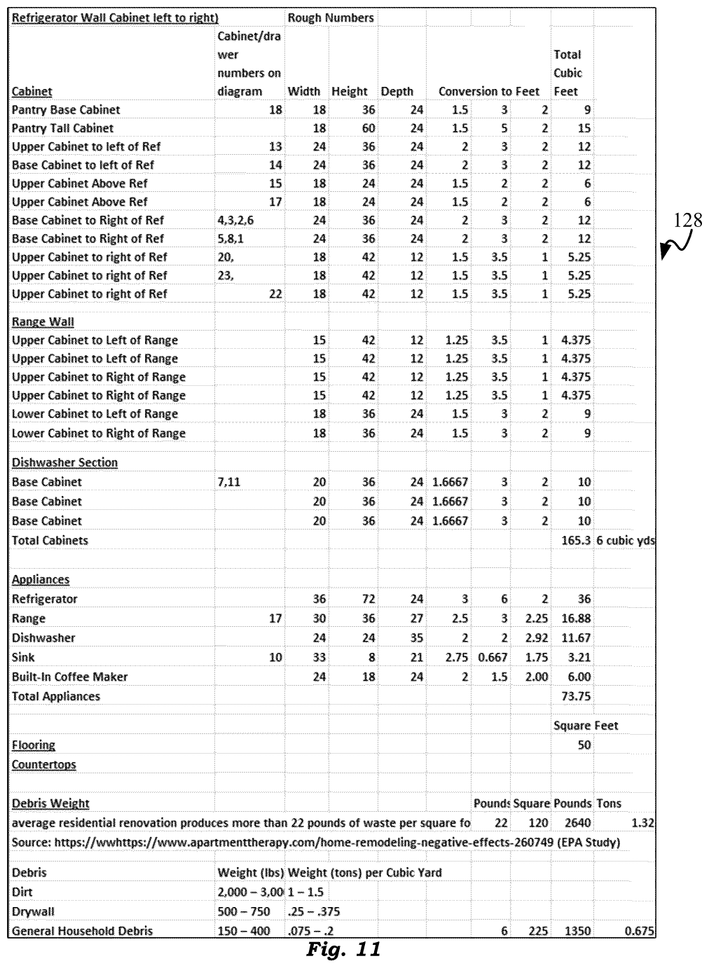

FIG. 8 shows that by utilizing computer vision and AI techniques of the above teachings, an existing kitchen scene 470 is analyzed to identify a hot region (for a cooking range), a wet region (for a sink) and a cold region (for a refrigerator) in the kitchen. FIG. 9 shows a kitchen scene 480 being analyzed for measuring the dimensions of the room, appliances and its cabinetry. Specifically, FIG. 9 shows the measurement lines traced on the scene for performing the measurements. FIG. 10 shows the reconstruction of an as-is kitchen 490 by 3D reconstruction module 334 and digital twin service 310 of the above teachings. More specifically, the various faces and dimensions of the cabinets in the kitchen are identified as shown. FIG. 11 shows an exemplary BOM or items list report 128 referred to as a kitchen plan summary report generated by the instant platform.

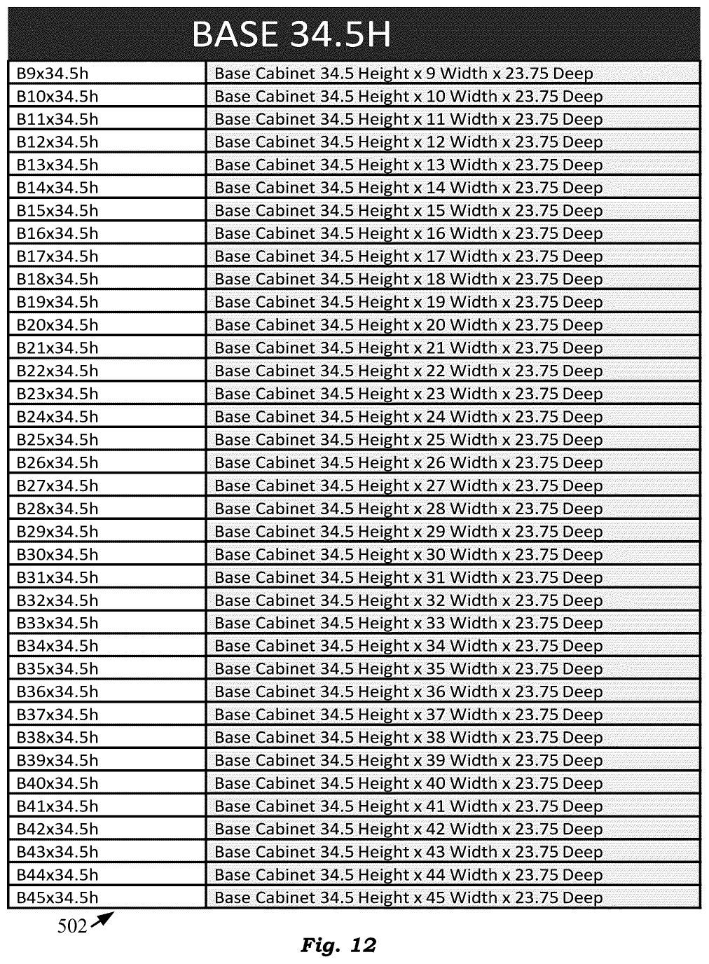

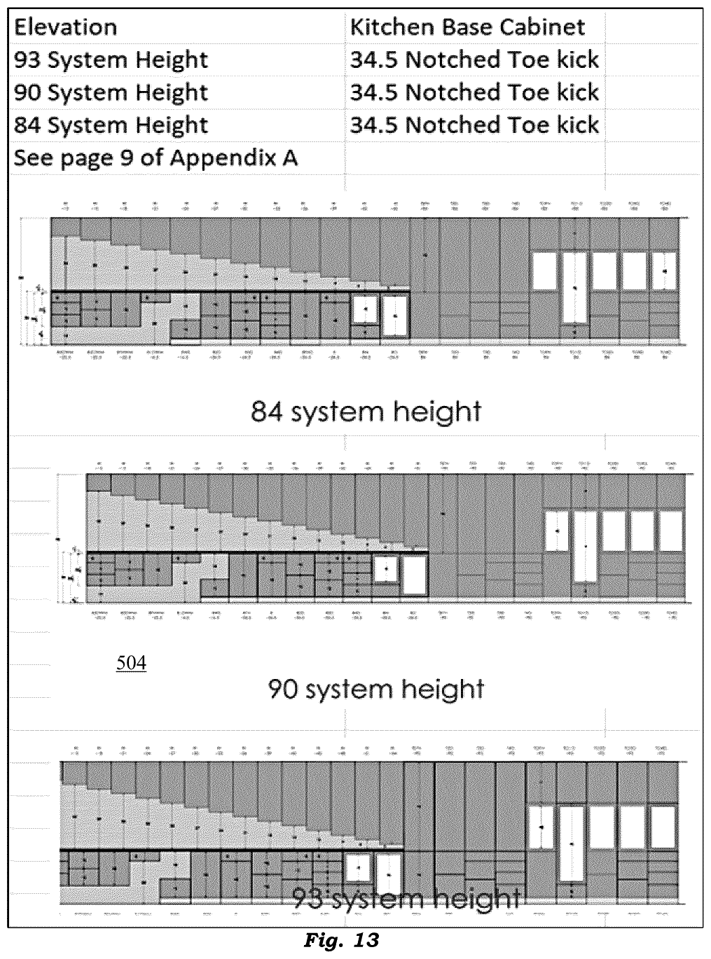

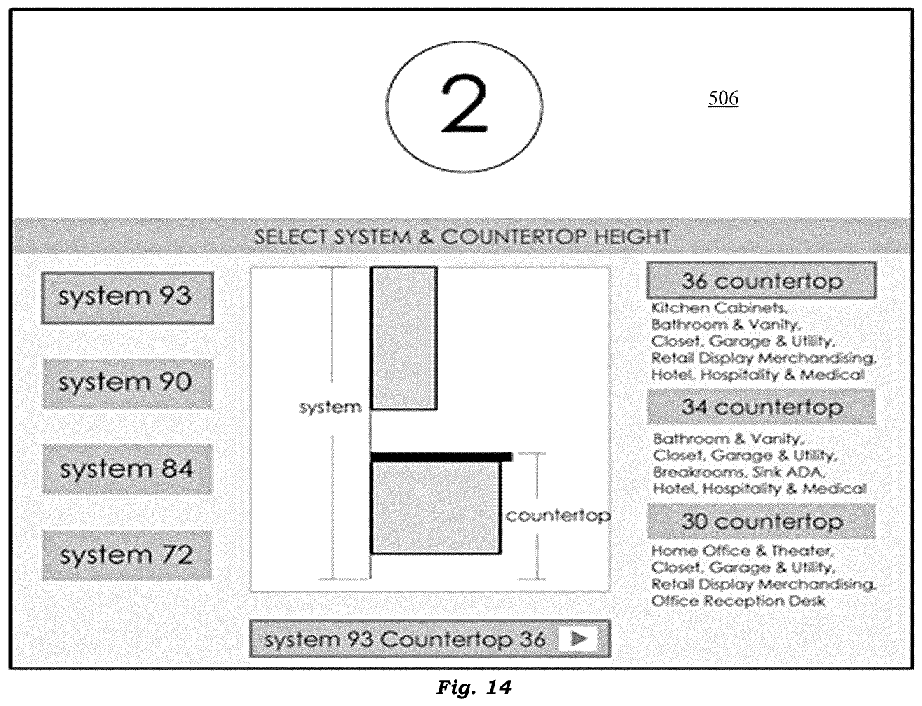

FIG. 12 shows an excerpt 502 from cabinets database 130 of the above teachings. Based on the standardized sizing information contained in database 130, SGSE 102 can implement rules that determine the dimensional and BOM information for a given kitchen renovation project. For example, for item #B9x34.5h shown in the first column of the first row, the system can determine the weight, cost and many other attributes of the item. So, during the capture phase, once the correct size and item number of a given kitchen asset is asset is identified and saved, this provides the information to be included in the BOM for the project. Furthermore, once the coordinates for this item are established in the kitchen, the dimensional information contained in database 130 can be used to generate a 2D layout (file 124) for the project that can be consumed by contractors or other appropriate stakeholders. FIG. 13 and FIG. 14 provide two visual representations 504 and 506 respectively of further excerpts of such a 1×3 system/database based on the instant principles.

Table 2 below provides another excerpt of the instant cabinets database 130. Per above teachings, the instant cabinets database is preferably consulted for generating the 3D models or 3D digital twin files of the kitchens.

TABLE 2

| | | | | | | | | |
|---|---|---|---|---|---|---|---|---|
| | | | Sub | Sub | Sub | | | |
| Nomenclature | Cabinet | Categories | Category | Category | Category | Width | Height | Depth |

| | | | | | | |
|---|---|---|---|---|---|---|
| | Wall | | | | | |
| | Units | | | | | |
| W912 | Wall | Wall | Single Door | 9 | 12 | 12 |
| W1012 | Wall | Wall | Single Door | 10 | 12 | 12 |
| W1112 | Wall | Wall | Single Door | 11 | 12 | 12 |
| W1212 | Wall | Wall | Single Door | 12 | 12 | 12 |
| W1312 | Wall | Wall | Single Door | 13 | 12 | 12 |
| W1812 | Wall | Wall | Single Door | 18 | 12 | 12 |
| W1912 | Wall | Wall | Single Door | 19 | 12 | 12 |
| W2012 | Wall | Wall | Single Door | 20 | 12 | 12 |
| W2112 | Wall | Wall | Single Door | 21 | 12 | 12 |
| W2212 | Wall | Wall | Single Door | 22 | 12 | 12 |
| W2312 | Wall | Wall | Single Door | 23 | 12 | 12 |
| W2412 | Wall | Wall | Single Door | 24 | 12 | 12 |
| W915 | Wall | Wall | Single Door | 9 | 15 | 12 |
| W1015 | Wall | Wall | Single Door | 10 | 15 | 12 |
| W1115 | Wall | Wall | Single Door | 11 | 15 | 12 |
| W1215 | Wall | Wall | Single Door | 12 | 15 | 12 |
| W1815 | Wall | Wall | Single Door | 18 | 15 | 12 |
| W1915 | Wall | Wall | Single Door | 19 | 15 | 12 |
| W2015 | Wall | Wall | Single Door | 20 | 15 | 12 |
| W2115 | Wall | Wall | Single Door | 21 | 15 | 12 |
| W2215 | Wall | Wall | Single Door | 22 | 15 | 12 |
| W2315 | Wall | Wall | Single Door | 23 | 15 | 12 |
| W2415 | Wall | Wall | Single Door | 24 | 15 | 12 |
| W918 | Wall | Wall | Single Door | 9 | 18 | 12 |
| W1018 | Wall | Wall | Single Door | 10 | 18 | 12 |
| W1118 | Wall | Wall | Single Door | 11 | 18 | 12 |
| W1218 | Wall | Wall | Single Door | 12 | 18 | 12 |
| W1318 | Wall | Wall | Single Door | 13 | 18 | 12 |
| W1918 | Wall | Wall | Single Door | 19 | 18 | 12 |
| W2018 | Wall | Wall | Single Door | 20 | 18 | 12 |
| W2118 | Wall | Wall | Single Door | 21 | 18 | 12 |
| W2218 | Wall | Wall | Single Door | 22 | 18 | 12 |
| W2318 | Wall | Wall | Single Door | 23 | 18 | 12 |
| W2418 | Wall | Wall | Single Door | 24 | 18 | 12 |
| W921 | Wall | Wall | Single Door | 9 | 21 | 12 |
| W1021 | Wall | Wall | Single Door | 10 | 21 | 12 |
| W1121 | Wall | Wall | Single Door | 11 | 21 | 12 |
| W1721 | Wall | Wall | Single Door | 17 | 21 | 12 |
| W1821 | Wall | Wall | Single Door | 18 | 21 | 12 |
| W1921 | Wall | Wall | Single Door | 19 | 21 | 12 |
| W2021 | Wall | Wall | Single Door | 20 | 21 | 12 |
| W2121 | Wall | Wall | Single Door | 21 | 21 | 12 |
| W2221 | Wall | Wall | Single Door | 22 | 21 | 12 |
| W2321 | Wall | Wall | Single Door | 23 | 21 | 12 |
| W2421 | Wall | Wall | Single Door | 24 | 21 | 12 |
| W924 | Wall | Wall | Single Door | 9 | 24 | 12 |
| W1024 | Wall | Wall | Single Door | 10 | 24 | 12 |
| W1124 | Wall | Wall | Single Door | 11 | 24 | 12 |
| W1224 | Wall | Wall | Single Door | 12 | 24 | 12 |
| W1324 | Wall | Wall | Single Door | 13 | 24 | 12 |
| W1424 | Wall | Wall | Single Door | 14 | 24 | 12 |
| W2024 | Wall | Wall | Single Door | 20 | 24 | 12 |
| W2124 | Wall | Wall | Single Door | 21 | 24 | 12 |
| W2224 | Wall | Wall | Single Door | 22 | 24 | 12 |
| W2324 | Wall | Wall | Single Door | 23 | 24 | 12 |
| W2424 | Wall | Wall | Single Door | 24 | 24 | 12 |
| W927 | Wall | Wall | Single Door | 9 | 27 | 12 |
| W1027 | Wall | Wall | Single Door | 10 | 27 | 12 |
| W1127 | Wall | Wall | Single Door | 11 | 27 | 12 |
| W1227 | Wall | Wall | Single Door | 12 | 27 | 12 |
| W1327 | Wall | Wall | Single Door | 13 | 27 | 12 |
| W1827 | Wall | Wall | Single Door | 18 | 27 | 12 |
| W1927 | Wall | Wall | Single Door | 19 | 27 | 12 |
| W2027 | Wall | Wall | Single Door | 20 | 27 | 12 |
| W2127 | Wall | Wall | Single Door | 21 | 27 | 12 |
| W2227 | Wall | Wall | Single Door | 22 | 27 | 12 |
| W2327 | Wall | Wall | Single Door | 23 | 27 | 12 |
| W2427 | Wall | Wall | Single Door | 24 | 27 | 12 |
| W930 | Wall | Wall | Single Door | 9 | 30 | 12 |
| W1030 | Wall | Wall | Single Door | 10 | 30 | 12 |
| W1130 | Wall | Wall | Single Door | 11 | 30 | 12 |
| W1230 | Wall | Wall | Single Door | 12 | 30 | 12 |
| W1330 | Wall | Wall | Single Door | 13 | 30 | 12 |
| W1830 | Wall | Wall | Single Door | 18 | 30 | 12 |
| W1930 | Wall | Wall | Single Door | 19 | 30 | 12 |
| W2030 | Wall | Wall | Single Door | 20 | 30 | 12 |
| W2130 | Wall | Wall | Single Door | 21 | 30 | 12 |
| W2230 | Wall | Wall | Single Door | 22 | 30 | 12 |
| W2330 | Wall | Wall | Single Door | 23 | 30 | 12 |
| W2430 | Wall | Wall | Single Door | 24 | 30 | 12 |
| W933 | Wall | Wall | Single Door | 9 | 30 | 12 |
| W1033 | Wall | Wall | Single Door | 10 | 30 | 12 |
| W1133 | Wall | Wall | Single Door | 11 | 33 | 12 |
| W1233 | Wall | Wall | Single Door | 12 | 33 | 12 |
| W1333 | Wall | Wall | Single Door | 13 | 33 | 12 |
| W1833 | Wall | Wall | Single Door | 18 | 33 | 12 |
| W1933 | Wall | Wall | Single Door | 19 | 33 | 12 |
| W2033 | Wall | Wall | Single Door | 20 | 33 | 12 |
| W2133 | Wall | Wall | Single Door | 21 | 33 | 12 |
| W2233 | Wall | Wall | Single Door | 22 | 33 | 12 |
| W2333 | Wall | Wall | Single Door | 23 | 33 | 12 |
| W2433 | Wall | Wall | Single Door | 24 | 33 | 12 |
| W936 | Wall | Wall | Single Door | 9 | 36 | 12 |
| W1036 | Wall | Wall | Single Door | 10 | 36 | 12 |
| W1136 | Wall | Wall | Single Door | 11 | 36 | 12 |
| W1236 | Wall | Wall | Single Door | 12 | 36 | 12 |
| W1336 | Wall | Wall | Single Door | 13 | 36 | 12 |
| W1836 | Wall | Wall | Single Door | 18 | 36 | 12 |
| W1936 | Wall | Wall | Single Door | 19 | 36 | 12 |
| W2036 | Wall | Wall | Single Door | 20 | 36 | 12 |
| W2136 | Wall | Wall | Single Door | 21 | 36 | 12 |
| W2236 | Wall | Wall | Single Door | 22 | 36 | 12 |
| W2336 | Wall | Wall | Single Door | 23 | 36 | 12 |
| W2436 | Wall | Wall | Single Door | 24 | 36 | 12 |
| W939 | Wall | Wall | Single Door | 9 | 39 | 12 |
| W1039 | Wall | Wall | Single Door | 10 | 39 | 12 |
| W1139 | Wall | Wall | Single Door | 11 | 39 | 12 |
| W1239 | Wall | Wall | Single Door | 12 | 39 | 12 |
| W1339 | Wall | Wall | Single Door | 13 | 39 | 12 |

In view of the above teachings, a person skilled in the art will recognize that the methods of present invention can be embodied in many different ways in addition to those described without departing from the principles of the invention. Therefore, the scope of the invention should be judged in view of the appended claims and their legal equivalents.

What is claimed is:

1. A method comprising the steps of:
(a) uploading to a sustainable goods and services exchange (SGSE), a first image file by a first property owner and a second image file by a second property owner, said first image file generated by a first imaging system used by said first property owner and said second image file generated by a second imaging system used by said second property owner, said first image file and said second image file containing images of a first kitchen and a second kitchen at a first property and a second property respectively, said first property and said second property owned by said first property owner and said second property owner respectively;
(b) utilizing by said SGSE, one or both of artificial intelligence (AI) and computer vision, for processing said first image file and said second image file to produce a first three dimensional (3D) digital twin file and a second 3D digital twin file respectively, each of said first 3D digital twin file and said second 3D digital twin file containing a first set of digital assets and a second set of digital assets respectively, said first set of digital assets corresponding to a first set of physical assets in said first kitchen and said second set of digital assets corresponding to a second set of physical assets in said second kitchen;
(c) enabling said first property owner and said second property owner to post onto said SGSE, one or more digital assets from amongst said first set of digital assets and said second set of said digital assets;
(d) allowing said second property owner access to said SGSE as a paid subscriber for selecting and overlaying onto said images of said second kitchen, at least one of said one or more digital assets posted onto said SGSE;
(e) generating by said SGSE, a first computer-aided design (CAD) file and a second CAD file for said first kitchen and said second kitchen respectively, said first CAD file used for deconstruction of said first kitchen by a first contractor and said second CAD file used for deconstruction and construction of said second kitchen by a second contractor; and
(f) generating a first diversion report and a second diversion report for said first kitchen and said second kitchen respectively.

2. The method of claim 1, wherein said SGSE comprises a user experience (UX) module, an application service module, an artificial intelligence (AI), computer vision and analytics module, a data infrastructure module, an external integrations module and an administration and monitoring module.

3. The method of claim 2, wherein said AI, computer vision and analytics module performs object detection based on a machine learning framework.

4. The method of claim 1 further allowing a charitable organization user access to said SGSE for accessing one or more of said first set of digital assets and said second set of digital assets from amongst said one or more digital assets posted onto said SGSE, for donating corresponding one or more of said first set of physical assets and said second set of physical assets to a charitable cause.

5. The method of claim 1 further allowing a deconstruction appraisal company user access to said SGSE for accessing one or more of said first set of digital assets and said second set of digital assets from amongst said one or more digital assets posted onto said SGSE, for appraising corresponding one or more of said first set of physical assets and said second set of physical assets.

6. The method of claim 5 further comprising the step of obtaining a tax benefit for said first property owner based on said appraising.

7. The method of claim 5 further comprising the step of obtaining a tax benefit for said second property owner based on said appraising.

8. The method of claim 1 consulting a cabinets database.

9. The method of claim 8, wherein said cabinets database comprises a first set of dimensions of one or more cabinets in said first kitchen and said second kitchen, and relationships between said first set of dimensions and a second set of dimensions of one or more of walls, floors and ceilings of said first kitchen and said second kitchen.

10. The method of claim 1 assigning by said SGSE, a first kitchen identification number (KIN) to said first kitchen and a second KIN to said second kitchen.

11. A sustainable goods and service exchange (SGSE) comprising:
(a) a user experience (UX) module for uploading to said SGSE, a first image file by a first property owner and a second image file by a second property owner, said first image file generated by a first imaging system used by said first property owner and said second image file generated by a second imaging system used by said second property owner, said first image file and said second image file containing images of a first kitchen and a second kitchen at a first property and a second property respectively, said first property and said second property owned by said first property owner and said second property owner respectively; and
(b) an artificial intelligence (AI), computer vision and analytics module for processing said first image file and said second image file and to produce by a digital twin service, a first three dimensional (3D) digital twin file and a second 3D digital twin file respectively, each of said first 3D digital twin file and said second 3D digital twin file containing a first set of digital assets and a second set of digital assets respectively, said first set of digital assets corresponding to a first set of physical assets in said first kitchen and said second set of digital assets corresponding to a second set of physical assets in said second kitchen;
wherein said SGSE further enables said first property owner and said second property owner to post onto said SGSE, one or more digital assets from amongst said first set of digital assets and said second set of said digital assets, and wherein said SGSE further allows said second property owner access to said SGSE as a paid subscriber for selecting and overlaying onto said images of said second kitchen, at least one of said one or more digital assets posted onto said SGSE,
and wherein said SGSE generates a first computer-aided design (CAD) file and a second CAD file for said first kitchen and said second kitchen respectively, said first CAD file used for deconstruction of said first kitchen by a first contractor and said second CAD file used for deconstruction and construction of said second kitchen by a second contractor, and wherein said SGSE generates a first diversion report and a second diversion report for said first kitchen and said second kitchen respectively.

12. The SGSE of claim 11, further comprising an application service module, a data infrastructure module, an external integrations module and an administration and monitoring module.

13. The SGSE of claim 11, further comprising an external integrations module for integrating with one or more of a non-governmental organization (NGO), a tax authority and a payment processor.

14. The SGSE of claim 11, wherein a charitable organization user accesses one or more of said first set of digital assets and said second set of digital assets from amongst said one or more digital assets posted onto said SGSE, for donating corresponding one or more of said first set of physical assets and said second set of physical assets to a charitable cause.

15. The SGSE of claim 11, wherein a deconstruction appraisal company user accesses one or more of said first set of digital assets and said second set of digital assets from amongst said one or more digital assets posted onto said SGSE, for appraising corresponding one or more of said first set of physical assets and said second set of physical assets.

16. The SGSE of claim 15, wherein a tax benefit is obtained for said first property owner based on said appraising.

17. The SGSE of claim 15, wherein a tax benefit is obtained for said second property owner based on said appraising.

18. The SGSE of claim 11, further comprising a cabinets database.

19. The SGSE of claim 18, wherein said cabinets database comprises a first set of dimensions of one or more cabinets in said first kitchen and said second kitchen, and relationships between said first set of dimensions and a second set of dimensions of one or more of walls, floors and ceilings of said first kitchen and said second kitchen.

20. The SGSE of claim 1, wherein a first kitchen identification number (KIN) is assigned to said first kitchen and a second KIN is assigned to said second kitchen.
